(19) United States
(12) Patent Application Publication
(10) Pub. No.: US 2015/0295196 A1
(43) Pub. Date: Oct. 15, 2015

(54) Method of producing a photovoltaic device

(71) Applicant: OPTITUNE OY, Oulu (FI)

(72) Inventors: Ari Kärkkäinen, Singapore (SG); Milja Hannu-Kuure, Oulu (FI); Henna Järvitalo, Oulu (FI); Paul Williams, Singapore (SG); Jarkko Leivo, Oulu (FI); Admir Hadzic, Oulu (FI); Jianhui Wang, Singapore (SG)

(21) Appl. No.: 14/430,559

(22) PCT Filed: Sep. 24, 2013
(86) PCT No.: PCT/FI2013/050927

§ 371 Date: Mar. 24, 2015

Related U.S. Application Data
(60) Provisional application No. 61/704,771, filed on Sep. 24, 2012.

(30) Foreign Application Priority Data
Sep. 24, 2012 (FI) 20125989

(51) Int. Cl. H01L 51/44; H01L 51/00

(52) U.S. Cl. CPC H01L 51/448; H01L 51/0004; H01L 51/0003; H01L 51/0008; H01L 2031/0344

(57) ABSTRACT

A method of producing a photovoltaic device which comprises a solar cell substrate forming the bulk of the device with at least one layer deposited thereon defining a surface of the device, said method comprising the step of introducing a functional layer on the substrate, said layer being capable of releasing hydrogen, and activating said layer to achieve hydrogenation of the photovoltaic device. The method makes it possible, in the case of thick film solar cell production, to have the whole manufacturing sequence performed using chemicals applied under atmospheric conditions.

### TECHNICAL FIELD

The present invention relates to solar cell structures and method of producing the same. In particular the present invention concerns structures wherein there are incorporated functional layers capable of achieving hydrogenation and passivation of the structures. The present invention also concerns the use of hybrid and inorganic chemicals (pre-cursor, molecules, polymers or intermediates) in solar cells, applied in combination with surface treatments, process, methods of delivery and activation of the chemistry and surface resulting in tunable levels of hydrogenation and passivation, resulting in higher free carrier lifetimes of photo-generated excitons and subsequent efficiency of the solar device.

### BACKGROUND ART

Photovoltaic devices (PV), commonly referred to as solar cells, have historically been manufactured from high purity single crystal, lattice matched semiconductor alloys where, due to the absence of dislocations, very few traps are encountered by free electrons generated in the photo voltaic process. The only traps are located at the surface between the device and air. These traps are generated by the surface configuration of the dangling bonds. These occur where the three dimensional crystallographic nature of the atoms terminates at the air/crystal interface.

To reduce or eliminate these traps, manufacturers have conventionally been using additional thin layers on the front surface. These additional layers have excellent matching characteristics to the device structure thereby removing the traps from the device, and physically separate the surface recombination from the device layer. In addition the material and thus optical parameters of such additional layers can be chosen to reduce the reflectivity of the incumbent layers in the device to enhance the light absorbed by the device and, as a consequence, increase the efficiency of the device.

When Silicon was originally evaluated as an inexpensive substrate for PV devices, thermally grown SiO₂ or sputtered TiO₂ were used for the additional thin layer on the front side of the PV. The SiO₂ gave excellent mechanical matching to the bulk Si—Si and TiO₂ and provided excellent optical properties, reducing the reflection at the surface from 33% to below 4%, the inclusions resulting in significant improvement in efficiency.

It was also established that different deposition recipes and post processing anneals could contribute to improvements in the efficiency of the devices.

In addition, manufacturers have continued to evaluate different materials for the additional thin layers. Silicon Nitride was identified as an alternative but introduction as a replacement to these incumbent materials has taken a number of years to implement due to reliability issues in film quality and optical properties generated by means other than thermally grown or by sputtering.

Recently, due to improvements in Plasma Enhanced Chemical Vapour Deposition (PECVD) tools and technology, SiNx has rapidly replaced SiO₂ and TiO₂ in new manufacturing lines. In addition to the improved tuneability of the optical properties from process and composition, and also the additional mechanical matching, there is an additional advantage to switch to PECVD SiNx, due to the method of manufacture. SiNx is grown in a vacuum chamber, where plasma is formed at low pressure in the presence of Ammonia (NH₃) and Silane (SiH₄). As a result of the formation of the SiNx there is an abundance of free hydrogen ions and radicals available. It is postulated that the uptake of the free hydrogen also contributes to improvements in performance due to the ability of these highly mobile ions to bind directly to available dangling bonds as part of the formation of the SiNx hydrogenation layer, SiNx:H.

Due to the complexity of the PECVD process, and the relatively high cost of the PECVD tools, it has recently be reported that layers formed from liquid phase deposition can be produced with the same optical performance as the vacuum deposited TiO or SiNx (cf. U.S. Pat. No. 7,094,709).

It is an aim of the present invention to further improve the manufacturing technology of the art and to provide a method of providing hydrogenation and passivation control in solar cells through activation of functional layers formed by chemical deposition.

In particular, it is an aim of the present invention to control the degree of hydrogenation of the PV device without the use of harmful gases.

### SUMMARY OF INVENTION

The present invention is based on the principle of delivering a chemical onto the surface of a PV device, and activating the chemical such that it introduces hydrogen into the bulk as well as onto the surface of the PV device. As a result, there is an increase in the efficiency of the current extraction and reduction of recombination occurring within the device. This results in greater power output from the device.

According to an aspect of the invention, there is provided a method for delivering a hydrogenating and passivating chemical (pre-cursor, molecules, polymers or intermediates) onto the surface of a solar cell surface, which includes at least one of the following steps: a) liquid phase deposition [LP]; b) sub-atmospheric deposition [ASD]; c) atomic layer deposition [ALD]; d) spray coat deposition; e) roller coat deposition; f) dip coat deposition; g) slot coat deposition and h) screen print/silk screen coat deposition.

In another aspect of the invention, the surface of the PV device is pretreated in order to promote the activation of the hydrogenation and passivation of the deposited chemical (pre-cursor, monomer, polymer, intermediate, catalyst or solvent), to enable the hydrogenation process.

In yet another aspect of the invention, a method is provided for forming the hydrogenating and passivating coating on a solar cell, the method comprising the use of two or more vessels containing a) component 1 (pre-cursor, monomer, polymer, intermediate, catalyst or solvent) and b) component 2 (pre-cursor, monomer, polymer, intermediate or solvent) as well as a mixing chamber and heat/irradiation chamber.

In such method, component 1 and component 2 are subjected to the forming of a product in the mixing chamber and the product is transferred to the PV device to form the hydrogenation and passivating coating.

In still a further aspect of the invention, the atmosphere into which the coated PV device is introduced is modified to activate at least one of the chemical components selected from pre-cursor, monomer, polymer, intermediate, catalyst and solvent, whereupon the activated atmosphere acts as the catalyst or pre-cursor acting on the deposited coating on the device to enable the hydrogenation to proceed.

A further embodiment of the invention relates to the provision of specific combinations of reagents (monomers, pre-cursors, polymers and intermediate) to provide the hydrogenation and passivation. The present invention relates to synthesis and polymerization of a hybrid organic-inorganic polymer compositions and intermediate compositions that are capable of achieving hydrogenation and passivation, which makes them suitable for use in fabrication of solar cells as described in the present context.

### Advantageous Effects of Invention

Considerable advantages are obtained by the present invention. Thus, the disclosed technology offers an alternative to the existing PECVD methods using NH₃ and SiH₄ gases, enabling the PV manufacturers to apply chemicals rather than work with hazardous gases to produce a series of layers that provide hydrogenation and passivation as well as light absorbing layers such as in the method of U.S. Pat. No. 7,094,709. The present technology makes it possible, in the case of thick film solar cell production, to have the whole manufacturing sequence performed using chemicals applied under atmospheric conditions and without the use of any hazardous gas or PECVD with the additional benefit of improvement in the tuneability of the level of hydrogenation and passivation.

### BRIEF DESCRIPTION OF DRAWINGS

FIG. 1 is a schematic representing the deposition of the chemical onto the surface of the PV device, the possible pretreatment and finally the activation process resulting in hydrogenation of the bulk and surface of the PV device;

FIGS. 2a-2b are cross-section schematics representing the pre-treatment of the device surface through a) a chemical process and b) a gaseous process;

FIG. 3 is a schematic diagram of a chemical delivery system for activating the chemistry in-situ at the PV device coating system; and

FIG. 4 is a schematic diagram of the coating system and the subsequent manipulation of the atmosphere during the post coating processing to activate the chemistry.

### DESCRIPTION OF EMBODIMENTS

As discussed above, the present invention comprises applying a chemical or chemicals onto a surface of a PV device to form a thin, typically dielectric, layer or layers. The thickness of the layer or layers are in the nm range (1-1000 nm), typically the thickness is from 5 to 250 nm single layer thickness. The formed layer acts as a passivation and hydrogenation layer, and it can be also combined with e.g. an anti-reflection layer for the silicon device. Upon treatment, the chemical hydrogen-releasing layer is activated and it then introduces hydrogen into the bulk as well as onto the surface of the PV device.

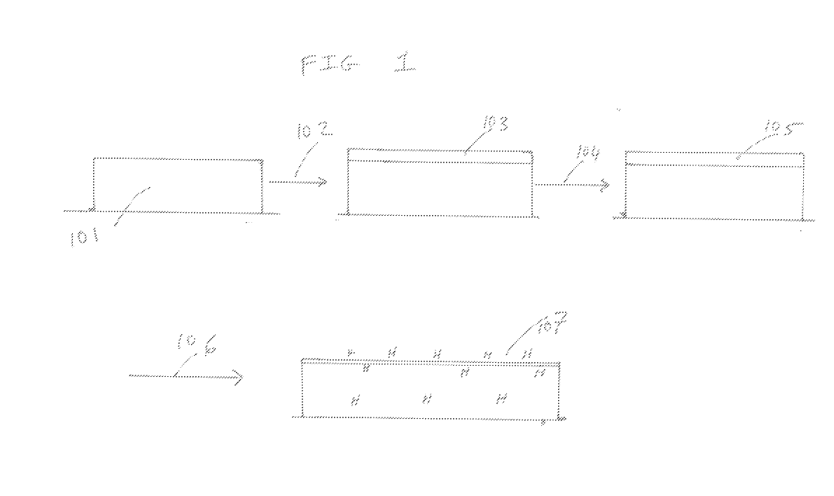

This is also illustrated in FIG. 1. Thus, reference numeral 101 stands for a solar cell substrate. On top of the substrate 101 there is first deposited a layer 103 by the introduction of a suitable chemical reagent 102. In the next step, there is an optional pretreatment of the deposited layer 103 to form a modified layer by the introduction of a second chemical reagent 104. Finally, after an activation process 106, hydrogenation 107 of the bulk and surface of the PV device is achieved as suggested by the letters H in the last depiction.

As a result of hydrogenation, greater power output from the device is achieved.

Embodiments of the above may include one or several of the following (in the following, the:
The coating is a pre-cursor, i.e. a compound which can form or release a desired chemical species, a monomer, polymer or intermediate or a combination thereof;
The coating is activated when brought into contact with the surface;
The coating is activated after a thermal process;
The coating is activated after irradiation with either UV, visible or IR radiation;
The coating is activated when introduced into an activating atmosphere;
The coating is contacted on the PV device surface with a chemical (pre-cursor, monomer, polymer or intermediate) already deposited on the surface;
The coating is contacted with the PV device surface following a pre-treatment of the surface enabling the chemical (pre-cursor, monomer, polymer or intermediate) to become activated;
The coating is activated when a second chemical (pre-cursor, monomer, polymer or intermediate) is deposited onto the coating;
The chemical (pre-cursor, monomer, polymer or intermediate) is activated during the deposition process onto the surface—as a result of the deposition method (Including the transfer from pump, reservoir, tubing and dispense head); and
The coating is activated when exposed to ultrasonic process.

For the deposition of layers in the above disclosed process, various deposition techniques as well as combinations thereof can be used. These are illustrated by the following embodiments:
1. Liquid phase deposition [LP] of pre-cursors, molecules, polymers and mixtures/additives as coatings to provide passivation, anti-reflective and other enhanced performance layers;
2. Sub-atmospheric deposition [ASD] of pre-cursors, molecules, polymers and mixtures/additives as coatings to provide passivation, anti-reflective and other enhanced performance layers;
3. Atomic layer deposition [ALD] of pre-cursors, molecules, polymers and mixtures/additives as coatings to provide passivation, anti-reflective and other enhanced performance layers;
4. Spray coat deposition of pre-cursors, molecules, polymers and mixtures/additives as coatings to provide passivation, anti-reflective and other enhanced performance layers;
5. Roller coat deposition of pre-cursors, molecules, polymers and mixtures/additives as coatings to provide passivation, anti-reflective and other enhanced performance layers;
6. Dip coat deposition of pre-cursors, molecules, polymers and mixtures/additives as coatings to provide passivation, anti-reflective and other enhanced performance layers;
7. Slot coat deposition of pre-cursors, molecules, polymers and mixtures/additives as coatings to provide passivation, anti-reflective and other enhanced performance layers; and
8. Screen print/silk screen coat deposition of pre-cursors, molecules, polymers and mixtures/additives as coatings to provide passivation, anti-reflective and other enhanced performance layers.

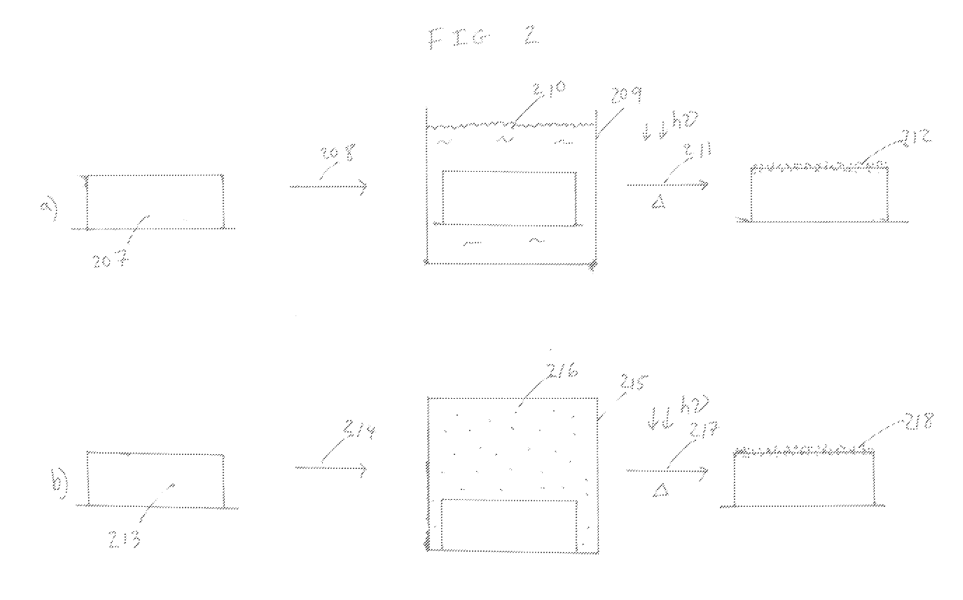

FIGS. 2 to 4 illustrate specific embodiments of the invention.

In FIG. 2a, a solar cell substrate 207 is introduced either automatically or manually 208 into a vessel 209 (e.g. wet bench, or equivalent) where the surface of the device is covered with the liquid chemical 210 (e.g. Acid, base, chemical solution). Following this exposure the substrate is removed and then undergoes a process 211 (addition of enthalpy and/or Irradiation) to complete the pre-treatment process (e.g. cross linking, oxidation, reduction, photocatalysis) completing the surface preparation resulting in a surface modified by the process and ready for chemical coating of the hydrogenating chemical 212.

Referring to FIG. 2b, a solar cell substrate 213 is introduced either automatically or manually 214 into an enclosed vessel 215 (e.g. furnace, oven, vacuum chamber). Here an activating chemistry is introduced into the vessel in gaseous form 216 (e.g. forming gas). Following this exposure the substrate is removed and then undergoes a process 217 (addition of enthalpy and/or Irradiation) to complete the pre-treatment process (e.g. cross linking, oxidation, reduction, photocatalysis) completing the surface preparation resulting in a surface modified by the process and ready for chemical coating of the hydrogenating chemical 218.

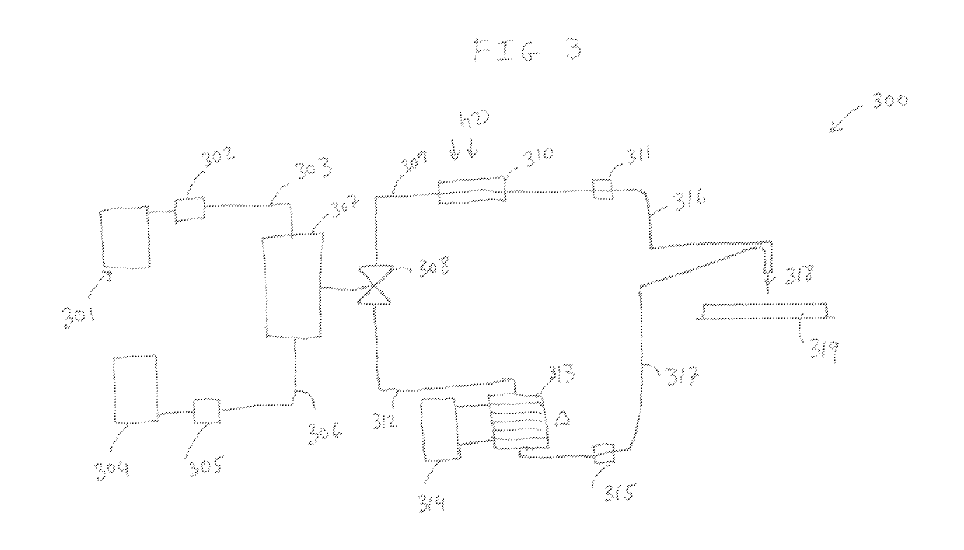

FIG. 3 shows a system 300 enabling the formation of a chemical (pre-cursor, monomer, polymer or intermediate) activating the chemistry in-situ at the point of delivery. The system 300 includes a vessel 301 for holding component 1 it also includes a vessel 304 containing the second component. Pump 302 transfers component 1 to the mixing vessel 307 through tube 303. Similarly, a pump 305 transfers component 2 to the mixing vessel 307 through tube 306. The mixture is directed by a valve 308 to the path 309 if the mixture requires activation by irradiation, and along path 312 if the mixture requires thermal activation. An Irradiation vessel 310 is incorporated along the tubing 309, where the mixture is exposed to either visible, ultraviolet or Infrared light activating the chemistry (e.g. free radicals, ionization etc.). Similarly a heat exchanger 313 electronically connected to a heater 314 set at the appropriate temperature so that the product is altered to have the desired characteristics (e.g. free radicals, ionization etc.). The product is then pumped from the irradiation vessel 310 by pump 311 along tube 316, and the product is pumped from the heat exchanger 313 by pump 315 along tube 317. The products can then combine at the dispense line 318 if both components are necessary, or a single activated component from either vessel 310 or 317 is required, and coated onto the solar cell substrate 319.

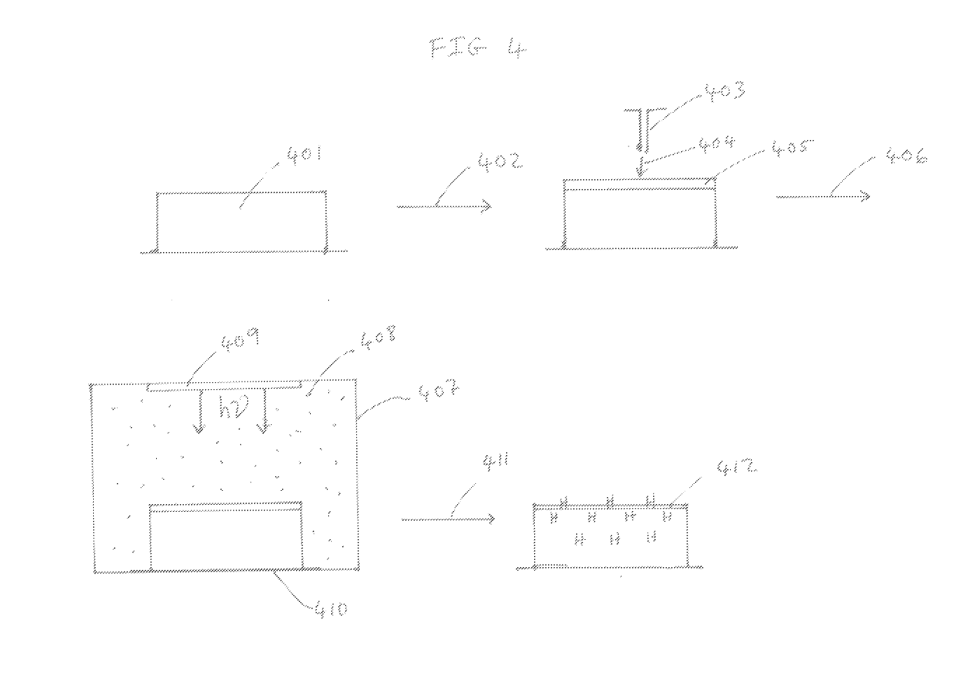

FIG. 4 illustrates an embodiment wherein the PV solar cell substrate 401 is introduced through an automated handling system 402 to the coating machine where the chemical is dispensed through a nozzle 403. The liquid phase deposition 404 can be carried out by sub-atmospheric deposition [ASD]; atomic layer deposition [ALD]; spray coat deposition; roller coat deposition; dip coat deposition; slot coat deposition or screen print/silk screen coat deposition. This results in the coated film 405 uniformly deposited on the substrate 401. The coated substrate is then transferred via automated handling 406 either at atmospheric ambient conditions or in an isolated inert atmosphere to the reaction vessel 407. Following the loading of the substrate, the reactive component 408 (e.g. catalyst or monomer or pre-cursor) is introduced in the vapour/gaseous phase into the chamber.

The atmosphere and coated substrate undergo a reaction which is initiated under irradiation from the lamp 409 and/or enthalpy provided by heat introduced into the vessel from heating elements 410. After the reaction is complete the substrate is removed by automated handling 411 to undergo the next deposition process. The substrate at this stage has undergone hydrogenation of the bulk and surface 412 facilitating higher free carrier lifetimes.

Table 1 lists process parameters for p-type screen printed solar cell using LPD dielectrics at the front compared to that using PECVD SiNx

TABLE 1

| | | LPD | | (LPD |
|---|---|---|---|---|
| | PECVD | dielectrics | (PECVD | AR + PECVD |
| | SiNx | (AR + MH) | SiN + MH) | SiN + MH) |
| Substrate | p-type | p-type | p-type | p-type |
| material | (100) | (100) | (100) | (100) |
| | FZ, | FZ, | FZ, | FZ, |
| | 1.5Ω · cm | 1.5Ω · cm | 1.5Ω · cm | 1.5Ω · cm |
| Wafer | 200 | 200 | 200 | 200 |
| thickness, | | | | |
| μm | | | | |
| Emitter | 70 | 70 | 70 | 70 |
| Rsh, Ω/□ | | | | |
| LPD SiOx | NA | 10 | 10 | 10 |
| thickness, | | | | |
| nm | | | | |
| LPD SiOx RI | NA | 1.45 | 1.45 | 1.45 |
| @ 633 nm | | | | |
| SiNx | 75 | NA | 70 | 10 |
| thickness, nm | | | | |
| SiNx RI | 2.0 | NA | 2.0 | 2.0 |
| @ 633 nm | | | | |
| LPD TiOx | NA | 30 | NA | 25 |
| thickness, | | | | |
| nm | | | | |
| LPD TiOx RI | NA | 2.50 | NA | 2.50 |
| @ 633 nm | | | | |
| LPD TaOx | NA | 30 | NA | 25 |
| thickness, | | | | |
| nm | | | | |
| LPD TaOx RI | NA | 1.90 | NA | 1.90 |
| @ 633 nm | | | | |

In respect to the above discussion on hydrogenation and passivation, it should be pointed out that positively charged SiOx is well suitable for passivation for the emitter (sunny side) of p-type solar cell and for the back side of n-type solar cell due to the formation of accumulation layer through surface band-bending. Hydrogenation from SiOx further reduces both surface and bulk recombination velocity through chemical passivation of defects, which ties up the dangling bonds and reduces Dit (density of interface states).

Aluminium oxide is a highly negatively charged dielectric which provides excellent passivation for the back side of p-type solar cell or for the front side of n-type solar cell by forming an accumulation layer by surface field effect (band-bending).

With AlOx deposited on the back side of p-type solar cell, improved passivation is achieved compared to Al-BSF, while avoiding the parasitic shunting that would occur from using positively charged SiOx or SiNx.

The surface of a PV device can be modified using a pre-treatment that can enable subsequent chemicals to become active or adhere more efficiently to the surface.

For example, the pre-treatments may be performed on the wafer or device using puddle formation on the surface, with multiple components or multiple steps.

Similarly the in-situ mixing may be done through circulation and the mixture may be three or more different components brought together through the system described.

In addition further components can be introduced after the first activation stage and further modules added with further mixing and processes in sequence prior to the delivery onto the substrate. Due to the potential of activity life-time, it may be necessary to shroud all piping with temperature controlled lagging.

A further example where modification may be made is the handling of the substrate before and after the delivery of the chemical.

Due to the many different application methods, it may be necessary to perform all handling in an inert atmosphere (e.g. nitrogen blanket), vacuum or high concentration of vapourized solvent. Consequently the reaction vessel may form an integral part of the transport system (e.g. belt furnace system for diffusion).

In addition to the above, the present technology can be combined with structuring methods and inclusions/combinations for enhanced adhesion, performance and coating quality of pre-cursors, molecules, polymers and mixtures/additives as coatings to provide passivation, anti-reflective and other enhanced performance layers.

It is also possible to carry out novel layer inclusions/combinations for enhanced adhesion, performance and coating quality of pre-cursors, molecules, polymers and mixtures/additives as coatings to provide passivation, anti-reflective and other enhanced performance layers.

One embodiment for improved activation, performance and coating quality of pre-cursors, molecules, polymers and mixtures/additives as coatings to provide passivation, anti-reflective and other enhanced performance layers comprises selective annealing, co-firing/activation bakes, and UV exposure.

The various substances used, pre-cursors, molecules, polymers and mixtures/additives, can be in-situ mixing at or immediately before deposition as coatings to provide passivation, anti-reflective and other enhanced performance layers.

In the present technology comprising hydrogenation and passivation control in solar cells through activation of functional layers formed by chemical deposition, the functional layers can be formed from a number of materials.

In a preferred embodiment, the functional layers are formed from hybrid organic-inorganic polymers or silane polymers or carbosilane polymers. The polymers can be produced from various intermediates, precursors and monomers.

In a preferred embodiment, the functional layers, which also can be called hydrogen releasing and passivating layers, are formed from siloxane/silane polymers, hybrid organic-inorganic polymers or carbosilane polymers. The polymers can be produced from various intermediates, precursors and monomers.

Furthermore, the above mentioned polymers contain at least one monomer, precursor or polymer that has a group or a substituent or a part of the molecules that has a hydrogen atom, and which capable of releasing that hydrogen atom, in particular in subsequent processing steps of the functional layer in solar cell manufacturing process. The hydrogen releasing monomer can be a silane precursor, for example trimethoxysilane, triethoxysilane (generally any trialkoxysilane, wherein alkoxy has 1 to 8 carbon atoms), a trihalosilane, such as trichlorosilane, or similar silanes, in particular of the kind which contain at least one hydrogen after hydrolysis and condensation polymerization. It can be used as monomeric additive in the coating material or hydrolyzed and condensated as part of the material backbone matrix. Also other silane types can be used as hydrogen releasing entities, including bi-silanes, and carbosilanes which contain hydrogen moiety. Generally, it is required that the hydrogen releasing group or substituent or part of the molecule contains a hydrogen which is bonded to a metal or a semimetal atom, preferably to a metal or a semimetal atom in the polymeric structure forming the layer. The hydrogen can also be bonded to a carbon atom, provided that the hydrogen is released upon treatment of the functional layers.

Hybrid organic-inorganic polymers can be synthesized by using silane or metal (or semimetal) oxide monomers or, and in particular, combinations of silane and metal oxide monomers as starting materials. Furthermore, the final coating chemical (precursor, monomer, polymer, intermediate, catalyst or solvent) has hydrogen moiety in the composition and that hydrogen being able to be released then during the solar cell manufacturing process to provide hydrogenation and passivation qualities. The polymers and intermediates have a siloxane backbone comprising repeating units of —Si—C—Si—O and/or —Si—O— and/or —Si—C—Si—C. Generally, in the formula (—Si—O—)ₙ and in the formula (—Si—C—Si—O—)ₙ and in the formulas (—Si—C—)ₙ the symbol n stands for an integer 4 to 10,000, in particular about 10 to 5000. In the case of using hybrid silane and metal oxide monomers the polymer and intermediates have a backbone comprising repeating units —Si—O-Me-O (where Me indicates metal atom such as Ti, Ta, Al or similar). The hybrid silane-metal oxide backbone can be also different to this.

Hybrid organic-inorganic polycondensates can be synthesized by using metal alkoxides and/or metal salts as metal precursors. Metal precursors are first hydrolysed, and metal alkoxides are typically used as the main source for the metal precursors. Due to the different hydrolysis rate, the metal alkoxides must be first hydrolysed and then chelated or otherwise inactivated in order to prevent self-condensation into monocondensate Me-O-Me precipitates. In the presence of water, this can be controlled by controlling the pH, which controls the complex ions formation and their coordination. For example, aluminum can typically form four-fold coordinated complex-ions in alkaline conditions and six-fold coordinated complex-ions in acidic conditions. By using metal salts as co-precursors, such as nitrates, chlorides, sulfates, and so on, their counter-ions and their hydrolysable metal complex-ions can conduct the formation of different coordination states into the final metal precursor hydrolysate.

Once a hydrolysed metal precursor is achieved, the next step is to introduce the silica species into the chelated or inactivated metal precursor solution. Silica sources are first dissolved and hydrolysed, at least partially, either directly in the metal precursor solution or before its introduction into the metal precursor solution. During or after the introduction, the partially or fully hydrolysed silica species are then let to react with the metal hydrolysate to form a polycondensate. The reaction can be catalyzed by altering the temperature, concentration, temperature, and so on, and it typically occurs at higher temperatures than room temperature. Due to the nature of metal complex-ions in general, it is often common that the polycondensates resembles rather a nanoparticulate structure than a linear polymer, which therefore has to be further electrochemically or colloidally stabilized to sustain its nanosized measures in the coating solution. During processing, the solution further forms a coating that will have its final degree of condensation after heat-treatment, where the major part of rest of the hydrolyzed groups are removed.

Again for example triethoxysilane (or another one of the above mentioned monomers) can be used as the hydrogen releasing moiety in the material. The Triethoxysilane is hydrolyzed and condensation polymerized example with the metal (semimetal) alkokside to results in final product. It is also possible to make the synthesis from halogenide based precursor and other types as well.

In the polymeric structures disclosed above, there is preferably a releasable hydrogen directly bonded to a metal or semimetal atom.

There can be up to one releasable hydrogen attached to each repeating metal or semimetal atom of the backbone.

The precursor molecules of the siloxane and/or metal (semimetal) oxide polymers can be penta-, tetra-, tri-, di-, or mono-functional molecules. A penta-functional molecule has five hydrolysable groups; tetra-functional molecule has four hydrolysable groups; a tri-functional molecule has three hydrolysable groups; a di-functional molecule has two; and mono-functional molecule has one. The precursor molecules, i.e. silane and metal oxide monomers can be have organic functionalities. The precursor molecules can be also bi-silanes and especially in case of some metal oxide or hybrid metal oxide it is possible to use some stabilizing agents in the composition in addition to other additives and catalyst. The molecular weight range for the siloxane and/or metal oxide coating material is in range of 400 to 150,000, preferably about 500 to 100,000, in particular about 750 to 50,000 g/mol.

A wet chemical coating is prepared from the coating solution by any typical liquid application (coating) processes, preferably with spin-on, dip, spray, ink-jet, roll-to-roll, gravure, flexo-graphic, curtain, drip, roller, screen printing coating methods, extrusion coating and slit coating, but are not limited to these.

According to one embodiment, the process according to the invention comprises hydrolyzing and polymerizing a monomers according to either or both of formulas I and II:

R¹ₐSiX₄₋ₐ I

and

R²_{b}SiX_{4-b} II
wherein R¹ and R² are independently selected from the group consisting of hydrogen, linear and branched alkyl and cycloalkyl, alkenyl, alkynyl, (alk)acrylate, epoxy, allyl, vinyl and alkoxy and aryl having 1 to 6 rings; each X represents independently halogen, a hydrolysable group or a hydrocarbon residue; and
   a and b is an integer 1 to 3.

Further, in combination with monomers of formula I or II or as such at least one monomer corresponding to Formula III can be employed:

R³_{c}SiX_{4-c} III
wherein R³ stands for hydrogen, alkyl or cycloalkyl which optionally carries one or several substituents, or alkoxy;
   each X represents independently halogen, a hydrolysable group or a hydrocarbon residue having the same meaning as above; and
   c is an integer 1 to 3.

In any of the formulas above, the hydrolysable group is in particular an alkoxy group (cf. formula IV).

As discussed above, in the present invention organosiloxane polymers are produced using tri- or tetraalkoxysilane. The alkoxy groups of the silane can be identical or different and preferably selected from the group of radicals having the formula

—O—R⁴ IV

wherein R⁴ stands for a linear or branched alkyl group having 1 to 10, preferably 1 to 6 carbon atoms, and optionally exhibiting one or two substitutents selected from the group of halogen, hydroxyl, vinyl, epoxy and allyl.

The above precursor molecules are condensation polymerized to achieve the final siloxane polymer composition. Generally, in case of tri-, di- and mono-functional molecules, the other functional groups (depending on the number of hydrolysable group number) of the precursor molecules can be organic functionalities such as linear, aryl, cyclic, aliphatic groups. These organic groups can also contain reactive functional groups e.g. amine, epoxy, acryloxy, allyl or vinyl groups. These reactive organic groups can optionally react during the thermal or radiation initiated curing step. Thermal and radiation sensitive initiators can be used to achieve specific curing properties from the material composition.

According to a preferred embodiment, when using the above monomers, at least one of the monomers used for hydrolysation and condensation is selected from monomers having formulas I or II, wherein at least one substituent is a group capable of providing the hydrogenation and passivation characteristics for the coated film. For preparing the prepolymer, the molar portion of units derived from such monomers (or the molar portion of monomers containing the active group calculated from the total amount of monomers) is about 0.1 to 100%, preferably about 20%-100%, in particular about 30% to 100%. In some cases, the group will be present in a concentration of about 30% based on the molar portion of monomers.

In the above polymers, the relation (molar ratio) between monomers providing releasable hydrogens in the polymeric material and monomers which do not contain or provide such hydrogens is preferably 1:10, in particular 5:10, preferably 10:10-1000:10. It is possible even to employ only monomers leaving a releasable hydrogen for the production of the polymer.

The carbosilane polymer can be synthesized for example by using Grignard coupling of chloromethyltrichlorosilane in the presence THF followed by reduction with lithium aluminum hydride. A general reaction route is given below. The end product contains two hydrogens bonded to the silicon atom which are capable being released during the processing of the silicon solar cell. The final product is dissolved in a processing solvent and can be processed as is using the liquid phase deposition. The final product can be used also as dopant, additive or reacted with silane or metal (or semimetal) backbone to results as coating material.

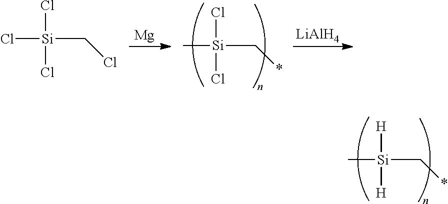

According to a preferred embodiment, when using the above monomers, at least one of the monomers used for hydrolysation and condensation is selected from monomers having formulas I or II, wherein at least one substituent is a group capable of providing the hydrogenation and passivation characteristics for the coated film. For preparing the prepolymer, the molar portion of units derived from such monomers (or the molar portion of monomers containing the active group calculated from the total amount of monomers) is about 0.1 to 100%, preferably about 20% to 100%, in particular about 30% to 100%. In some cases, the group will be present in a concentration of about 30% based on the molar portion of monomers.

According to one embodiment, at least 50 mol-% of the monomers are being selected from the group of tetraethoxysilane, triethoxysilane, tetramethoxysilane, trimethoxysilane, tetrachlorosilane, trichlorosilane, and mixtures thereof.

According to one embodiment, the solution coating polymer composition comprises a siloxane polymer, hybrid silane metal oxide polymer or carbosilane polymer in a solvent phase, wherein the partially cross-linked prepolymer has a siloxane or hybrid silane metal oxide or carbosilane backbone formed by repeating units and having a molecular weight in the range of from about 1,000 to about 15,000 g/mol, for example 2,000 to 10,000 g/mol. In addition, the (pre)polymer backbone exhibits 1 to 100 releasable hydrogen per 100 repeating units.

According to another embodiment, the siloxane composition comprises a siloxane polymer, hybrid silane metal oxide polymer or carbosilane polymer in a solvent phase, wherein
the partially cross-linked prepolymer has a siloxane backbone formed by repeating —Si—O— units and having a molecular weight in the range of from about 4,000 to about 10,000 g/mol, the siloxane backbone exhibiting hydroxyl groups in an amount of about 5 to 70% of the —Si—O— units and further exhibiting epoxy groups in an amount of 1 to 15 mol %, calculated from the amount of repeating units; and
the composition further comprises 0.1-3%, based on the weight of the solid matter, at least one cationic photo reactive compound.

The synthesis of the siloxane polymer is carried out in two steps. In the first synthesis step, in the following also called the hydrolysis step, the precursor molecules are hydrolyzed in presence typically of water and a catalyst, such as hydrochloric acid or nitric acid or another mineral or organic acid or a base, and in the second step, the polymerization step, the molecular weight of the material is increased by condensation polymerization or other crosslinking depending on what precursors are chosen to the synthesis. The water used in the hydrolysis step has typically a pH of less than 7, preferably less than 6, in particular less than 5.

It may be preferable in some cases to carry out the condensation polymerization in the presence of a suitable catalyst. In this step the molecular weight of the prepolymer is increased to facilitate suitable properties of the material and film deposition and processing.

The siloxane polymer synthesis, including the hydrolysis, the condensation and the cross-linking reactions, can be carried out using an inert solvent or inert solvent mixture, such as acetone or PGMEA, “non-inert solvent”, such as alcohols, or without a solvent. The used solvent affects the final siloxane polymer composition. The reaction can be carried out in basic, neutral or acidic conditions in the presence of a catalyst. The hydrolysis of the precursors may be done in the presence of water (excess of water, stoichiometric amount of water or sub-stoichiometric amount of water). Heat may be applied during the reaction and refluxing can be used during the reaction.

Typically before the further condensation the excess of water is removed from the material and at this stage it is possible to make a solvent exchange to another synthesis solvent if desired. This other synthesis solvent may function as the final or one of the final processing solvents of the siloxane polymer. The residual water and alcohols and other by-products may be removed after the further condensation step is finalized. Additional processing solvent(s) may be added during the formulation step to form the final processing solvent combination. Additives such as thermal initiators, radiation sensitive initiators, surfactants and other additives may be added prior to final filtration of the siloxane polymer. After the formulation of the composition, the polymer is ready for processing.

Suitable solvents for the synthesis are, for example, acetone, tetrahydrofuran (THF), toluene, 1-propanol, 2-propanol, methanol, ethanol, propylene glycol monomethyl ether, propylene glycol propyl ether, methyl-tert-butylether (MTBE), propylene glycol monomethylether acetate (PGMEA), propylene glycol monomethylether PGME and propylene glycol propyl ether (PnP), PNB, IPA, MIBK, Glycol Ethers (Oxitols, Proxitols), Butyl Acetates, MEK Acetate, or mixtures of these solvents or other suitable solvents.

After synthesis, the material is diluted using a proper solvent or solvent combination to give a solid content and coating solution properties which with the selected film deposition method will yield the pre-selected film thickness. Suitable solvents for the formulation are example 1-propanol, 2-propanol, ethanol, propylene glycol monomethyl ether, propylene glycol propyl ether (PNP), PNB (propandiol-monobutyl ether), methyl-tert-butylether (MTBE), propylene glycol monomethylether acetate (PGMEA), propylene glycol monomethylether PGME and PNB, IPA, MIBK, Glycol Ethers (Oxitols, Proxitols), Butyl Acetates, MEK Acetate, or mixtures of these solvents or other suitable solvents.

The final coating film thickness has to be optimized according for each device and structure fabrication process. In addition to using different solvents it is also possible to use surfactants and other additives to improve the coating film quality, wetting and conformality on the silicon cell.

Optionally, an initiator or catalyst compound is added to the siloxane composition after synthesis. The initiator, which can be similar to the one added during polymerization, is used for creating a species that can initiate the polymerization of the “active” functional group in the UV curing step. Thus, in case of an epoxy group, cationic or anionic initiators can be used. In case of a group with double bonds as “active” functional group in the synthesized material, radical initiators can be employed. Also thermal initiators (working according to the radical, cationic or anionic mechanism) can be used to facilitate the cross-linking of the “active” functional groups. The choice of a proper combination of the photoinitiators also depends on the used exposure source (wavelength). Also photoacid generators and thermal acid generators can be used to facilitate improved film curing.

The concentration of the photo or thermally reactive compound in the composition is generally about 0.1 to 10%, preferably about 0.5 to 5%, calculated from the mass of the siloxane polymer.

Film thicknesses may range e.g. from 1 nm to 500 nm. Various methods of producing thin films are described in U.S. Pat. No. 7,094,709, the contents of which are herewith incorporated by reference.

A film produced according to the invention typically has an index of refraction in the range from 1.2 to 2.4 at a wavelength of 633 nm.

The composition as described above may comprise solid nanoparticles in an amount between 1 and 50 wt-% of the composition. The nanoparticles are in particular selected from the group of light scattering pigments and inorganic phosphors or similar. By means of the invention, materials are provided which are suitable for producing films and patterned structures on silicon cells. The patterning of the thermally and/or irradiation sensitive material compositions can be performed via direct lithographic patterning, laser patterning and exposure, conventional lithographic masking and etching procedure, imprinting, ink-jet, screen-printing and embossing, but are not limited to these.

The compositions can be used for making layers which are cured at relatively low processing temperatures, e.g. at a temperature of max 375° C. or even at temperature of 100° C. and in the range between these limits.

However the coating layer formed from the material compositions can also be cured at higher temperatures, i.e. at temperatures over 375° C. and up to 900° C., or even up to 1100° C., making it possible for the material films or structures to be cured at a high temperature curing, such as can be combined with a subsequent high temperature deposition and firing steps.

In the following, there is presented a number of non-limiting working examples giving further details of the preparation of the above-discussed siloxane polymer, hybrid silane-metal oxide polymer and carbosilane coating compositions, suitable for forming passivating and hydrogen-releasing layers on silicon substrates in photovoltaic devices. These materials can be applied as discussed above in connection with the drawings.

### EXAMPLE 1

Tetraethyl orthosilicate (28.00 g) and Triethoxysilane (42.00 g) and solvent (ethanol) were weighted into the 1 L flask and stirred for 30 minutes. 0.01 M HCl (2× equivalent) was added. Material was refluxed for one hour. Solvent exchange was done to propylene glycol propyl ether (PnP). A further condensation polymerization was carried out in presence of catalyst (triethylamine). After this trimethylmethoxysilane (0.02 g) was added and further solvent exchange done to propylene glycol propyl ether (PnP). Material was diluted to process formulation and filtrated with 0.1 μm filter to obtain process ready solution.

### EXAMPLE 2

Tetraethyl orthosilicate (14.00 g) and Triethoxysilane (60.00 g) and solvent (2-propanol) were weighted into the 1 L flask and stirred for 30 minutes. 0.01 M HCl (0.6 equivalent) was added. Material was refluxed for one hour. Solvent exchange was done to propandiol-monobutyl ether (PNB). A further condensation polymerization was carried out in presence of catalyst (triethylamine). After this trimethylmethoxysilane (0.021 g) was added and further solvent exchange done to propylene glycol propyl ether (PnP). Material was diluted to process formulation and filtrated with 0.1 μm filter to obtain process ready solution.

### EXAMPLE 3

Methyl-trimethoxysilane (15.00 g), 3-Glycidoxypropyl-trimethoxysilane (9.00 g) and Triethoxysilane (75.00 g) and solvent (2-propanol) were weighted into the 1 L flask and stirred for 30 minutes. 0.01 M HCl (1 equivalent) was added. Material was refluxed for one hour. Solvent exchange was done to propylene glycol propyl ether (PnP). A further condensation polymerization was carried out in presence of catalyst (triethylamine). After this trimethylethoxysilane (0.025 g) was added and further solvent exchange done to propylene glycol propyl ether (PnP). Material was diluted to process formulation and filtrated with 0.1 μm filter to obtain process ready solution.

### EXAMPLE 4

Tetraethyl orthosilicate (5.00 g) and Triethoxysilane (82.00 g) and solvent (2-propanol) were weighted into the 1 L flask and stirred for 30 minutes. 0.01 M HCl (1 equivalent) was added. Material was refluxed for one hour. Solvent exchange was done to propylene glycol propyl ether (PnP). A further condensation polymerization was carried out in presence of catalyst (triethylamine). After this trimethylethoxysilane (0.025 g) was added and further solvent exchange done to propylene glycol propyl ether (PnP). Material was diluted to process formulation and filtrated with 0.1 μm filter to obtain process ready solution.

### EXAMPLE 5

Triethoxysilane (98.00 g) and solvent (2-propanol) were weighted into the 1 L flask and stirred for 30 minutes. 0.01 M HCl (0.6 equivalent) was added. Material was refluxed for one hour. Solvent exchange was done to propylene glycol propyl ether (PnP). A further condensation polymerization was carried out in presence of catalyst (triethylamine). After this trimethylchlorosilane (0.02 g) was added and further solvent exchange done to propylene glycol propyl ether (PnP). Material was diluted to process formulation and filtrated with 0.1 μm filter to obtain process ready solution.

### EXAMPLE 6

Aluminium nitrate-nonahydrate (180 g) in water solution was mixed with Aluminium isopropoxide (80 g). After that triethoxysilane (15 g) was added. Solution was refluxed for 4 hours. 1-propanol was added as processing solvent and filtrated with 0.1 μm filter to obtain process ready solution.

### EXAMPLE 7

Aluminium nitrate-nonahydrate (180 g) in water solution was mixed with Aluminium isopropoxide (40 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 8

Aluminium nitrate-nonahydrate (180 g) in water solution was mixed with Aluminium isopropoxide (20 g) and Titanium isopropoxide (25 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 9

Aluminium nitrate-nonahydrate (180 g) in water solution was mixed with Titanium (IV) isopropoxide (38 g). After that triethoxysilane (15 g) was added. Solution was refluxed for 4 hours. Solvent exchanged was performed to 1-propanol. The solution was filtrated with 0.04 μm filter to obtain process ready solution.

### EXAMPLE 10

Aluminium nitrate-nonahydrate (180 g) in water solution was mixed with Aluminium isopropoxide (20 g) and Tantalum ethoxide (22 g). After that triethoxysilane (15 g) was added. Solution was refluxed for 4 hours. Solvent exchanged was performed to 1-propanol. The solution was filtrated with 0.1 μm filter to obtain process ready solution.

### EXAMPLE 11

Aluminium nitrate-nonahydrate (180 g) in water solution was mixed with Aluminium isopropoxide (35 g). After that tetraethyl orthosilicate (5 g) and triethoxysilane (14 g) was added. Solution was refluxed for 4 hours. Solvent exchanged was performed to 1-propanol. The solution was filtrated with 0.04 μm filter to obtain process ready solution.

### EXAMPLE 12

20 g of Aluminium s-butoxide and 200 g of PGEE were mixed for 30 min. 15.58 g of Ethyl Acetoacetate was added and followed by addition of triethoxysilane (11 g) was added and mixed. Mixture of H₂O and PGEE (8 g and 40 g) was added. The solution was filtrated with 0.1 μm filter to obtain process ready solution.

### EXAMPLE 13

20 g of AlCl₃ was dissolved to EtOH (200 g) and TiCl₄ (10 g)+Ti(iOPr)₄ (14 g) was dissolved to 200 g of EtOH. Dissolved solutions were combined. Solution was stirred for 60 min at RT. Triethoxysilane (15 g) was added and solution was strirred at RT for 60 min. EtOH was distilled using membrane pump. 220 g of 2-isopropoxyethanol was added to the material flask. Solution was cooled down and filtrated. Solution was formulated to the final processing solvent 1-butanol and was filtrated with 0.1 μm filter to obtain process ready solution.

### EXAMPLE 14

Mg (8 g) was charged in reactor flask and the atmosphere was changed from air to N₂. Dry THF (175 ml) was added to Mg and Cl₃SiCH₂Cl (35 mL) was added at RT. Solution was refluxed for 4 hours. The reaction mixture was washed with dry THF and LiAlH₄ was added (4.0 grams). The solution was refluxed for 2 hours. The solvent was changed to pentane and extracted (300-400 mL). The solution was filtrated and solvent exchange was made to propylene glycol propyl ether (PnP). Material was diluted to process formulation and filtrated with 0.1 μm filter to obtain process ready solution.

### EXAMPLE 15

Mg (12 g) was charged in a reactor flask and the atmosphere was changed from air to N₂. Dry THF was added to Mg and Cl₃SiCH₂Cl (35 mL) was added at RT. CuCN was added to the reaction mixture. Solution was refluxed for 4 hours. The reaction mixture was washed with dry THF and LiAlH₄ was added (4.0 grams). The solution was refluxed for 2 hours. The solvent was changed to pentane and extracted (300-400 mL). The solution was filtrated and solvent exchange was made to propylene glycol propyl ether (PnP). The material was diluted to process formulation and filtrated with 0.1 μm filter to obtain process ready solution.

### EXAMPLE 16

Basic recipe: Place 704 grams of Titanium (IV) isopropoxide to reactor flask. Add 470 grams of titanium tetrachloride to reactor. Add 5760 ml of methanol to the reactor and stir the reaction solution for 2 hours.

MeOH was distilled using membrane pump, distillation apparatus and oil bath. 5872 grams of 2-isopropoxyethanol was added to the material flask. The solution was cooled down to −6° C. 1013 g of TEA was added the way that the material solution temperature was kept between −6° C. and +6° C. during TEA addition. The solution was filtrated using a Buchner funnel. The solution was cooled down in the reactor over night. Finally the solution was filtrated using a filter paper. The solution was formulated to the final processing solvent IPA and was ready for processing after final filtration.

### EXAMPLE 17

20 g of AlCl₃ was dissolved to 200 g of EtOH and TiCl₄(9.48 g)+Ti(iOPr)₄ (14.21 g) was dissolved to 200 g of EtOH. Dissolved solutions were combined. Solution was stirred for 60 min at RT. EtOH was distilled using membrane pump, distillation apparatus and oil bath. 220 g of 2-isopropoxyethanol was added to the material flask. The solution was cooled down to −6° C. 101.18 g of TEA was added in 10 min. Material solution temperature was kept between −6° C. and +6° C. during TEA addition. The solution was filtrated using a Buchner funnel. The solution was placed to the freezer over night. Finally the solution was filtrated using a filter paper. The solution was formulated to the final processing solvent EtOH and was ready for processing after final filtration.

### EXAMPLE 18

20 g of Aluminium s-butoxide and 200 g of PGEE were weighted to a round bottom flask and stirred at room temperature for 30 min. 15.58 g of Ethyl Acetoacetate was added drop-wise to the solution and stirring at room temperature was continued further 1 h. Mixture of H20/PGEE (8 g/40 g) was added to the clear solution dropwise by Pasteur pipette and solution was stirred at room temperature overnight. The solid content of the material is 4.49 w-%

### EXAMPLE 19

To a round bottom flask containing 182.7 of ANN-DI water, 42.27 g of Aluminum-isopropoxide (AIP) power was added during 40 min under strong stirring. After AIP addition, 19.18 g of TEOS was added drop-wise during 30 min. The clear solution was stirred over a night at room temperature. Solution was heated up to 60° C. using an oil bath and condenser and stirred at 60° C. for 4 hours. After 4 hours clear solution was further stirred at room temperature for over a night.

Solvent exchange was carried out from DI water to 1-propanol using a rotary evaporator with three 1-propanol addition steps (Water bath temperature 60° C.). The total amount of added 1-propanol was 136 g. Total amount of removed solution was 195 g. After solvent exchange solid content of the solution was 16.85 w-%.

1. A method of producing a photovoltaic device which includes a solar cell substrate forming the bulk of the device with at least one layer deposited thereon defining a surface of the device, said method comprising the step of:
introducing a functional layer on the substrate, said layer being capable of releasing hydrogen, and
activating said functional layer to achieve hydrogenation of the photovoltaic device.

2. The method according to claim 1, wherein the functional layer is formed by deposition on the substrate.

3. The method according to claim 1, wherein chemical deposition is activated such that it introduces hydrogen into the bulk as well as onto the surface of the PV device.

4. The method according to claim 1, wherein hydrogenation and passivation of the photovoltaic device is achieved.

5. The method according to claim 1, wherein the functional layer is formed from a chemical substance selected from precursors, molecules, polymers and intermediates, and combinations thereof.

6. The method according to claim 1, comprising at least one of the following steps:
the coating is activated when brought into contact with the surface;
the coating is activated after a thermal process;
the coating is activated after irradiation with UV, visible or IR radiation;
the coating is activated when introduced into an activating atmosphere;
the coating is contacted on the PV device with a chemical substance already deposited on the surface;
the coating is contacted with the PV device following a pre-treatment of the surface enabling the chemical to become activated;
the coating is activated by depositing a second chemical substance onto the coating;
the chemical is activated during the deposition process onto the surface; and
the coating is activated when exposed to an ultrasonic process.

7. The method according to claim 1, further comprising forming the coating by liquid phase deposition, a sub-atmospheric deposition, atomic layer deposition, spray coat deposition, roller coat deposition, dip coat deposition, slot coat deposition, or screen print or silk screen coat deposition.

8. The method according to claim 1, wherein the functional layer is deposited on the front and/or back side of the substrate.

9. The method according to claim 1, wherein the solar cell substrate comprises an n-type or p-type silicon substrate.

10. The method according to claim 1, comprising forming at least one additional layer having properties of passivation, anti-reflection and other properties enhanced performance on the substrate, either between the substrate and the functional layer or on top of the functional layer.

11. (canceled)

12. The method according to claim 1, wherein the functional layer comprises a silane or carbosilane or hybrid organic-inorganic polymer or intermediate.

13. The method according to claim 1, wherein the functional layer exhibits a chemical substance which has a hydrogen moiety in the composition which hydrogen is capable of being released then during further processing of the photovoltaic device to provide hydrogenation and passivation of said device.

14. The method according to claim 12, wherein the polymer or intermediate has a siloxane backbone comprising repeating units of —Si—C—Si—O and/or —Si—O— and/or —Si—C—Si—C.

15. The method according to claim 14, wherein in the polymer or intermediate has the formula (—Si—O—)ₙ or (—Si—C—Si—O—)ₙ or (—Si—C—)ₙ wherein n is an from 4 to 10,000.

16. The method according to claim 12, wherein hybrid silane and metal oxide monomers are used and the polymer and intermediates have a backbone comprising repeating units —Si—O-Me-O (where Me indicates metal atom such as Ti, Ta, Al or similar).

17. The method according to claim 1, wherein
the hydrogen release and passivating layer comprises silicon, oxygen and hydrogen for the emitter of p-type solar cell and for the back side of n-type solar cell;
the hydrogen release and passivating layer comprises silicon, carbon and hydrogen for the emitter of p-type solar cell and for the back side of n-type solar cell;
the hydrogen release and passivating layer comprises silicon, carbon, oxygen and hydrogen for the emitter of p-type solar cell and for the back side of n-type solar cell;
the hydrogen release and passivating layer comprises aluminium, oxygen, and hydrogen for the back side of p-type solar cell or for the front side of n-type solar cell;
the hydrogen release and passivating layer comprises titanium, oxygen, and hydrogen for the back side of p-type solar cell or for the front side of n-type solar cell;
the hydrogen release and passivating layer comprises aluminium, titanium, oxygen, and hydrogen for the back side of p-type solar cell or for the front side of n-type solar cell;
the hydrogen release and passivating layer is formed by polymerizing Si(OR¹)₄ and/or HSi(OR¹)₃, wherein R¹ is an alkyl group;
the passivating layer is formed by polymerizing Al(iOPr)₃ and Ti(iOPr)₄ and HSi(OR¹)₃ (for aluminium oxide);
wherein the passivating layer is formed by polymerizing Ti(iOPr)₄, HSi(OR¹)₃ and TiCl₄ (for titanium oxide); or
wherein the passivating layer is formed by polymerizing HSi(OR¹)₃ and Al(iOPr)₃ (for aluminium oxide and silicon oxide hybrid).

18. The method according to claim 1, wherein the functional layer comprises a siloxane or metal oxide coating material having a molecular weight in the range of 400 to 150,000 g/mol.

19. The method according to claim 1, comprising subjecting the solar cell substrate to a pre-treatment, in-situ and post deposition inclusions of pre-cursors, molecules, polymers and mixtures/additives as coatings to provide passivation, anti-reflective and other enhanced performance properties for the improvement of silicon and SiNx:H as an AR/passivation coating.

20. The method according to claim 1, comprising treating the photovoltaic device, so as to improve front and back side contact performance with, pre-cursors, molecules, polymers and mixtures/additives as coatings to provide passivation, anti-reflective and other enhanced performance layers.

21. (canceled)

22. A photovoltaic device comprising a solar cell substrate forming the bulk of the device and at least one layer deposited thereon defining a surface of the device, the photovoltaic device comprising a functional layer capable of releasing hydrogen upon activation to achieve hydrogenation of the photovoltaic device.
